(19) United States
(12) Patent Application Publication
(10) Pub. No.: US 2005/0224797 A1
(43) Pub. Date: Oct. 13, 2005

(54) CMOS fabricated on different crystallographic orientation substrates

(75) Inventors: Chih-Hsin Ko, Fongshan City (TW); Wen-Chin Lee, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/816,562

(22) Filed: Apr. 1, 2004

(51) Int. Cl. H01L 29/04

(52) U.S. Cl. 257/64

(57) ABSTRACT

A microelectronic device including a first substrate bonded to a second substrate. The first and second substrate may have different crystallographic orientations. The first substrate includes an opening through which an epitaxially grown portion of the second substrate extends. A first semiconductor device is coupled to the first substrate. A second semiconductor device is coupled to the epitaxially grown portion of the second substrate.

### BACKGROUND

The present disclosure relates generally to microelectronic devices and, more specifically, to a microelectronic device fabricated on substrates having different crystallographic orientations, a method of manufacture therefor, and an integrated circuit incorporating the same.

One transistor performance parameter of frequent discussion is electron mobility. This parameter is a measure of electron scattering in a semiconductor material, relating the proportionality between electron drift velocity and electric field as well as carrier concentration and conductivity of the semiconductor. Drift velocity relates the velocity of carriers under an electric field. That is, in contrast to carriers in free space, carriers in a semiconductor are not “infinitely” accelerated by an electric field due to scattering. Accordingly, carriers in a semiconductor reach a finite velocity regardless of the period of time over which the field is acting. At a given electric field, drift velocity is determined by the carrier mobility. Generally, increasing electron mobility provides an increase in performance of negative-biased transistors.

Another transistor performance parameter is hole mobility. This parameter is a measure of hole scattering in a semiconductor, relating the proportionality between hole drift velocity and electric field as well as conductivity and hole concentration in the semiconductor. Due to the higher effective mass of a hole, hole mobility is typically significantly lower than electron mobility. Generally, increasing hole mobility provides an increase in performance of positive-biased transistors.

According to some industry reports, electron mobility is maximized when employing substrates having a (1,0,0) crystalline orientation, and hole mobility is maximized when employing substrates having a (1,1,0) crystalline orientation. Thus, microelectronic devices employing positive-biased transistors are often formed on substrates having a (1,1,0) crystalline orientation, whereas microelectronic devices employing negative-biased transistors are often formed on substrates having a (1,0,0) crystalline orientation. However, for microelectronic devices employing complimentary transistor configurations in which neighboring pairs of transistors include one negative-biased transistor and one positive-biased device (e.g., CMOS devices), single-crystalline-orientation substrates achieve only one of increased hole mobility and increase electron mobility, because microelectronic device substrate (e.g., silicon wafers) generally have only one crystalline orientation.

Accordingly, what is needed in the art is a device and method of manufacture thereof that addresses the above-discussed issues.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A illustrates a sectional view of one embodiment of a microelectronic device in an intermediate stage of manufacture according to aspects of the present disclosure.

FIG. 1B illustrates a sectional view of the microelectronic device shown in FIG. 1A in a subsequent stage of manufacture.

FIG. 1C illustrates a sectional view of the microelectronic device shown in FIG. 1B in a subsequent stage of manufacture.

FIG. 1D illustrates a sectional view of the microelectronic device shown in FIG. 1C in a subsequent stage of manufacture.

FIG. 2A illustrates a sectional view of another embodiment of a microelectronic device in an intermediate stage of manufacture according to aspects of the present disclosure.

FIG. 2B illustrates a sectional view of the microelectronic device shown in FIG. 2A in a subsequent stage of manufacture.

FIG. 2C illustrates a sectional view of the microelectronic device shown in FIG. 2B in a subsequent stage of manufacture.

FIG. 2D illustrates a sectional view of the microelectronic device shown in FIG. 2C in a subsequent stage of manufacture.

FIG. 3A illustrates a sectional view of another embodiment of a microelectronic device in an intermediate stage of manufacture according to aspects of the present disclosure.

FIG. 3B illustrates a sectional view of the microelectronic device shown in FIG. 3A in a subsequent stage of manufacture.

FIG. 3C illustrates a sectional view of the microelectronic device shown in FIG. 3B in a subsequent stage of manufacture.

FIG. 3D illustrates a sectional view of the microelectronic device shown in FIG. 3C in a subsequent stage of manufacture.

FIG. 4 illustrates a sectional view of one embodiment of an integrated circuit device constructed according to aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

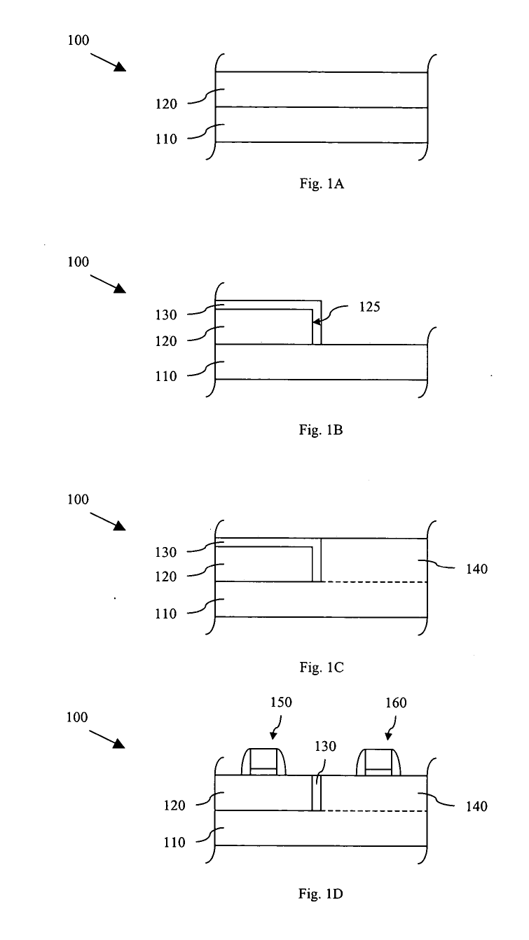

Referring to FIG. 1A, illustrated is a sectional view of one embodiment of a microelectronic device 100 in an intermediate stage of manufacture according to aspects of the present disclosure. The microelectronic device 100 includes a substrate 110 and a substrate 120.

The substrates 110, 120 may each comprise an elementary semiconductor (such as crystal silicon, polycrystalline silicon, amorphous silicon and germanium), a compound semiconductor (such as silicon carbide and gallium arsenide), an alloy semiconductor (such as silicon germanium, gallium arsenide phosphide, aluminum indium arsenide, aluminum gallium arsenide and gallium indium phosphide), combinations thereof and/or other materials. The substrates 110, 120 may also each comprise a semiconductor material on an insulator, such as a silicon-on-insulator (SOI) substrate, a silicon on sapphire (SOS) substrate, or a thin film transistor (TFT). In one embodiment, the substrates 110, 120 may also each include a doped epitaxial layer. The substrates 110, 120 may also each include a multiple silicon structure or a multilayer, compound semiconductor structure.

The substrates 110, 120 are bonded or otherwise coupled together. Such coupling may employ wafer bonding utilizing mirror-polished, flat and clean wafers. When two wafers are brought into contact, they may be locally attracted to each other by Van der Waals forces and thereby and thereafter bonded to each other. The wafer bonding process may be initiated by locally applying a slight pressure to the wafer pair, such that the bonded area may spread laterally over a substantial portion of the wafer contact area in a few seconds. In some embodiments, bonded wafer pairs may be exposed to a heat treatment to strengthen the bonding interface.

The substrates 110, 120 have different crystallographic orientations. For example, the substrate 110 may have a (1,1,0) crystallographic orientation and the substrate 120 may have a (1,0,0) crystallographic orientation. In another embodiment, the substrate 110 may have a (1,0,0) crystallographic orientation and the substrate 120 may have a (1,1,0) crystallographic orientation. Of course, the substrates 10, 120 may have crystallographic orientations other than those described above. In one embodiment, the different crystallographic orientations of the substrates 10, 120 may only be in adjacent portions of the substrates 110, 120. For example, the substrate 110 may comprise a layer that is adjacent a layer of the substrate 120, wherein the two adjacent layers have different crystallographic orientations, although the bulk portions of the substrates 110, 120 may have similar or other crystallographic orientations.

Referring to FIG. 1B, illustrated is a sectional view of the microelectronic device 100 shown in FIG. 1A in a subsequent stage of manufacture, in which a portion of the substrate 120 has been removed to expose a portion of the substrate 110. Such removal of a portion or portions of the substrate 120 may form one or more openings in the substrate 120 exposing the substrate 110. For example, one or more dry and/or wet etching processes may be employed to pattern the substrate 120. The etching process may comprise an isotropic etch, in which the rate of etching reaction is significant in more than one direction, or an anisotropic etch, which the rate of etching is more substantial in one or more predetermined directions than in other directions. The etching process may also employ photolithographic and/or masking process in which a portion of the substrate 120 is shielded from an etching composition.

As also shown, a dielectric film 130 may be formed over the second substrate 120 after the second substrate 120 has been patterned. The dielectric film 130 may be blanket deposited or otherwise conformally formed over the second substrate 120 such that the dielectric film 130 also substantially spans a sidewall 125 of the substrate 120 defined during the prior patterning processing.

The dielectric film 130 may be formed over the substrate 120 by thermal oxidation, atomic layer deposition (ALD), chemical vapor deposition (CVD), plasma-enhanced CVD (PECVD), physical vapor deposition (PVD), and/or other processes. Moreover, although not limited by the scope of the present disclosure, the dielectric film 130 may comprise oxide, silicon oxide, silicon nitride, silicon oxynitride, hafnium oxide, zirconium oxide, aluminum oxide, a hafnium dioxide-alumina (HfO₂—Al₂O₃) alloy, combinations thereof and/or other materials. A masking process may be employed to prevent formation of the dielectric film 130 on the substrate 110, or the deposition of the dielectric film 130 may be a selective deposition. An etching or other material removal process or a masking process may also be employed to remove any portion of the dielectric film 130 formed on the substrate 110. The dielectric film 130 may have a thickness ranging between about 5 Angstroms and about 100 Angstroms. Although not shown in the illustrated embodiment, one or more seed layers, adhesion layers, and/or diffusion barrier layers may also be formed between the dielectric film 130 and the substrate 120 and/or over the dielectric film 130.

Referring to FIG. 1C, illustrated is a sectional view of the semiconductor device 100 shown in FIG. 1B in a subsequent stage of manufacture, in which an extension 140 of the first substrate 110 has been formed in the void created by the patterning processing of the second substrate 120 described above. In one embodiment, the extension 140 may be epitaxially grown, such as by a selective epitaxial growth (SEG). The extension 140 may have a crystallographic orientation that is substantially similar or identical to the crystallographic orientation of the substrate 110 and different from the crystallographic orientation of the substrate 120. For example, the extension 140 and the substrate 110 may have a (1,1,0) crystallographic orientation and the substrate 120 may have a (1,0,0) crystallographic orientation. In another embodiment, the extension 140 and the substrate 110 may have a (1,0,0) crystallographic orientation and the substrate 120 may have a (1,1,0) crystallographic orientation. Chemical-mechanical polishing or chemical-mechanical planarizing (collectively referred to herein as CMP) may be employed to planarize the extension 140, such that the extension 140 may be substantially coplanar with the dielectric film 130.

Referring to FIG. 1D, illustrated is a sectional view of the semiconductor device 100 shown in FIG. 1C in a substrate stage of manufacture, in which semiconductor devices 150, 160 have been formed. The semiconductor devices 150, 160 may be or comprise metal-oxide-semiconductor field-effect-transistors (MOSFETs), Fin-FETs, memory cells, and/or other conventional or future-developed semiconductor devices. In one embodiment, the semiconductor devices 150, 160 may each be or comprise complimentary metal-oxide-semiconductor (CMOS) devices, such that one of the semiconductor devices 150, 160 may be or comprise an n-type transistor and the other of the semiconductor devices 150, 160 may be or comprise a p-type transistor. One or more CMP processes may be employed prior to forming the semiconductor devices 150, 160 such that the substrate 120, the dielectric film 130, and the extension 140 may collectively form a substantially coplanar surface on which the semiconductor devices 150, 160 may be formed.

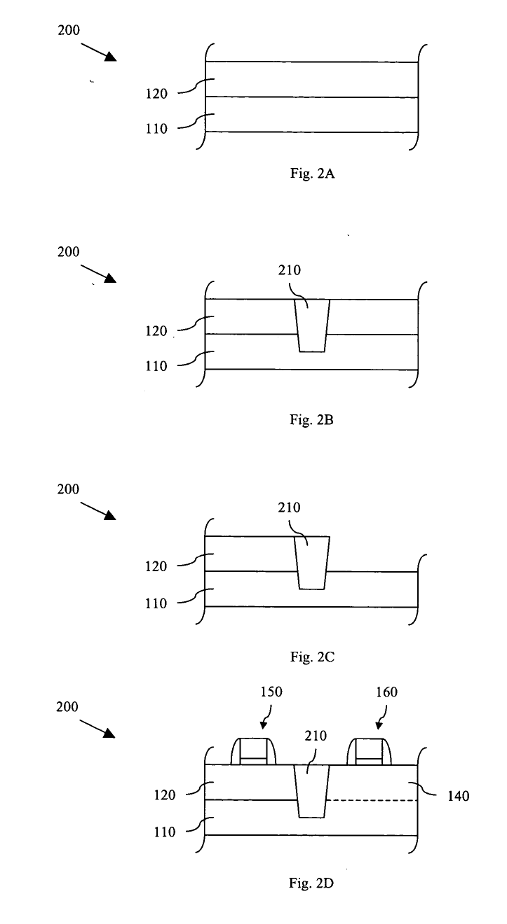

Referring to FIG. 2A, illustrated is a sectional view of another embodiment of a microelectronic device 200 in an intermediate stage of manufacture according to aspects of the present disclosure. The microelectronic device 200 may be substantially similar to the microelectronic device 100 shown in FIGS. 1A-1D. For example, the microelectronic device 200 includes coupled substrates 110, 120 which may be substantially similar to those shown in FIGS. 1A-1D.

Referring to FIG. 2B, illustrated is a sectional view of the microelectronic device 200 shown in FIG. 2A in a subsequent stage of manufacture. The microelectronic device 200 also includes an isolation structure 210 substantially spanning the thickness of the substrate 120 and extending at least partially into the substrate 110. The isolation structure 210 may also extend substantially through the substrate 110. In one embodiment, the isolation structure 210 is a shallow trench isolation (STI) element. The isolation structure 210 may be formed by etching or otherwise patterning a recess extending substantially through the substrate 120 and partially into the substrate 110. The recess may be filled with a bulk dielectric material, possibly after a diffusion barrier layer is deposited to line the recess. Of course, other isolation structures and methods of manufacture thereof are within the scope of the present disclosure.

Referring to FIG. 2C, illustrated is a sectional view of the microelectronic device 200 shown in FIG. 2B in a subsequent stage of manufacture, in which a portion of the substrate 120 has been removed or the substrate 120 has been otherwise patterned. The substrate 120 may be patterned by processes similar to those discussed above with reference to FIG. 1B.

Referring to FIG. 2D, illustrated is a sectional view of the microelectronic device 200 shown in FIG. 2C in a subsequent stage of manufacture, in which an extension 140 has been formed from the substrate 110 and adjacent the substrate 120. The extension 140 may be formed by processes similar to those discussed above with reference to FIG. 1C. FIG. 2D also illustrates the formation of semiconductor devices 150, 160 over the substrate 120 and the extension 140, respectively. The semiconductor devices 150, 160 and their manufacture may be substantially similar to those discussed above with reference to FIG. 1D.

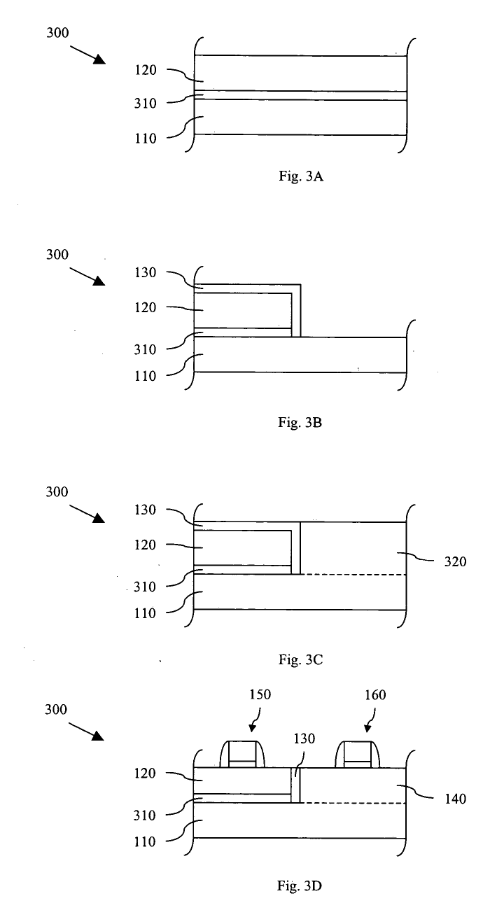

Referring to FIG. 3A, illustrated is a sectional view of another embodiment of a microelectronic device 300 in an intermediate stage of manufacture according to aspects of the present disclosure. The microelectronic device 300 may be substantially similar to the microelectronic device 100 shown in FIGS. 1A-1D. For example, the microelectronic device 300 includes coupled substrates 110, 120 which may be substantially similar to those shown in FIGS. 1A-1D.

However, the microelectronic device 300 also includes an insulator layer 310 interposing the substrates 110, 120. The insulator layer 310 may be formed over the substrate 110 by thermal oxidation, ALD, CVD, PECVD, PVD, and/or other processes. The insulator layer 310 may also be or comprise a buried oxide layer, such as that formed by implanting oxide and/or another insulator material through at least a portion of the substrate 120. Although not limited by the scope of the present disclosure, the insulator layer 310 may comprise oxide, silicon oxide, silicon nitride, silicon oxynitride, hafnium oxide, zirconium oxide, aluminum oxide, a hafnium dioxide-alumina (HfO₂—Al₂O₃) alloy, combinations thereof and/or other materials. The insulator layer 310 may have a thickness ranging between about 5 Angstroms and about 100 Angstroms. Although not shown in the illustrated embodiment, one or more seed layers, adhesion layers, and/or diffusion barrier layers may also be formed between the insulator layer 310 and the substrate 110 and/or over the insulator layer 310.

Referring to FIG. 3B, illustrated is a sectional view of the microelectronic device 300 shown in FIG. 3A in a subsequent stage of manufacture, in which a portion of the substrate 120 and the insulator layer 310 have been removed to expose a portion of the substrate 110. For example, one or more dry and/or wet etching processes may be employed to pattern the substrate 120. The etching process may comprise an isotropic etch, in which the rate of etching reaction is significant in more than one direction, or an anisotropic etch, which the rate of etching is more substantial in one or more predetermined directions than in other directions. The etching process may also employ a mask or masking process, thereby shielding a portion of the substrate 120 from the etching process.

As also shown, a dielectric film 130 may be formed over the second substrate 120 after the second substrate 120 has been patterned. The dielectric film 130 may be blanket deposited or otherwise conformally formed over the second substrate 120 such that the dielectric film 130 also substantially spans the insulator layer 310 and a sidewall 125 of the substrate 120 defined during the prior patterning processing.

The dielectric film 130 may be formed over the substrate 120 by thermal oxidation, ALD, CVD, PECVD, PVD, and/or other processes. Although not limited by the scope of the present disclosure, the dielectric film 130 may comprise oxide, silicon oxide, silicon nitride, silicon oxynitride, hafnium oxide, zirconium oxide, aluminum oxide, a hafnium dioxide-alumina (HfO₂—Al₂O₃) alloy, combinations thereof and/or other materials. A masking process may be employed to prevent formation of the dielectric film 130 on the substrate 110, or the deposition of the dielectric film 130 may be a selective deposition. An etching or other material removal process or a masking process may also be employed to remove any portion of the dielectric film 130 formed on the substrate 110. The dielectric film 130 may have a thickness ranging between about 5 Angstroms and about 100 Angstroms. Although not shown in the illustrated embodiment, one or more seed layers, adhesion layers, and/or diffusion barrier layers may also be formed between the dielectric film 130 and the substrate 120 and/or over the dielectric film 130.

Referring to FIG. 3C, illustrated is a sectional view of the semiconductor device 300 shown in FIG. 3B in a subsequent stage of manufacture, in which an extension 140 of the first substrate 110 has been formed in the void created by the patterning processing of the second substrate 120 described above. In one embodiment, the extension 140 may be epitaxially grown, such as by a selective epitaxial growth (SEG). The extension 140 may have a crystallographic orientation that is substantially similar or identical to the crystallographic orientation of the substrate 110 and different from the crystallographic orientation of the substrate 120. For example, the extension 140 and the substrate 110 may have a (1,1,0) crystallographic orientation and the substrate 120 may have a (1,0,0) crystallographic orientation. In another embodiment, the extension 140 and the substrate 110 may have a (1,0,0) crystallographic orientation and the substrate 120 may have a (1,1,0) crystallographic orientation. Chemical-mechanical polishing or chemical-mechanical planarizing (collectively referred to herein as CMP) may be employed to planarize the extension 140, such that the extension 140 may be substantially coplanar with the dielectric film 130.

Referring to FIG. 3D, illustrated is a sectional view of the microelectronic device 300 shown in FIG. 3C in a subsequent stage of manufacture, in which semiconductor devices 150, 160 have been formed over the substrate 120 and the extension 140, respectively. The semiconductor devices 150, 160 and their manufacture may be substantially similar to those discussed above with reference to FIG. 1D.

As also shown, a portion of the dielectric film 130 may be removed prior to forming the semiconductor devices 150, 160. For example, etching and/or CMP may be employed to remove the portion of the dielectric film 130 that is opposite the substrate 120 from the substrate 110, thereby exposing the substrate 120. Such processing may also be employed to remove a portion of the extension 140 such that the extension and the substrate 120 are substantially coplanar. However, the portion of the dielectric film 130 interposing the substrate 120 and the extension 140 may remain to electrically isolate the substrate 120 from the extension 140.

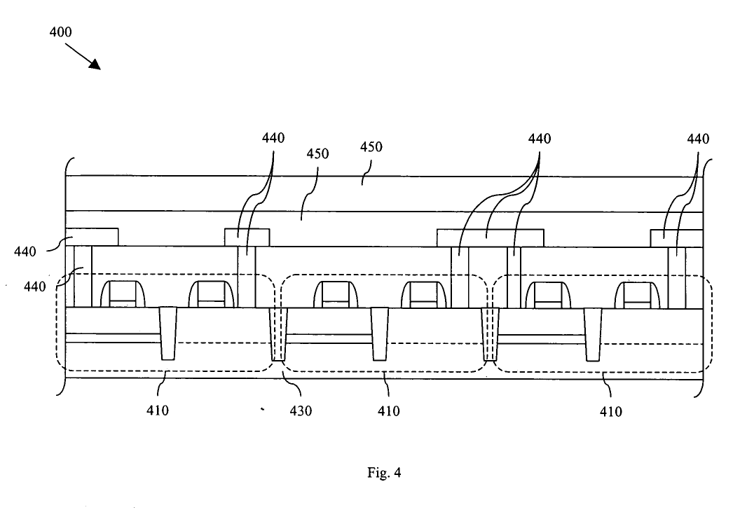

Referring to FIG. 4, illustrated is a sectional view of one embodiment of an integrated circuit device 400 constructed according to aspects of the present disclosure. The integrated circuit device 400 is one environment in which aspects of the above-described microelectronic devices may be implemented. For example, the integrated circuit device 400 includes a plurality of microelectronic devices 410 located on and/or in a substrate 430, one or more of which may be substantially similar to one or more of the microelectronic devices 100, 200, and 300 shown in FIGS. 1D, 2D, and 3D, respectively. The microelectronic devices 410 may be interconnected, and may be connected to one or more MOSFETs, Fin-FETs, memory cells, and/or other conventional or future-developed semiconductor devices manufactured on and/or in the substrate 430.

The integrated circuit device 400 also includes interconnects 440 extending along and/or through one or more dielectric layers 450 to ones of the plurality of microelectronic devices 410. The dielectric layers 450 may comprise silicon dioxide, Black Diamond® (a product by Applied Materials of Santa Clara, Calif.) and/or other materials, and may be formed by CVD, PECVD, ALD, PVD, spin-on coating and/or other processes. The dielectric layers 450 may have a thickness ranging between about 2000 Angstroms and about 15,000 Angstroms. The interconnects 440 may comprise copper, tungsten, gold, aluminum, carbon nano-tubes, carbon fullerenes, refractory metals, and/or other materials, and may be formed by CVD, ALD, PVD and/or other processes.

Thus, the present disclosure introduces a microelectronic device including, in one embodiment, a microelectronic device including a first substrate bonded to a second substrate. The first substrate includes an opening through which an epitaxially grown portion of the second substrate extends. A first semiconductor device is coupled to the first substrate, and a second semiconductor device is coupled to the epitaxially grown portion of the second substrate. In one embodiment, the first and second substrates have different crystallographic orientations.

The present disclosure also provides a method of manufacturing a microelectronic device. In one embodiment, the method includes coupling a first substrate to a second substrate and patterning an opening in the first substrate. The first and second substrates may have different crystallographic orientations. An extension of the second substrate is epitaxially grown through the opening. A first semiconductor device is formed on the first substrate, and a second semiconductor device is formed on the extension of the second substrate.

The present disclosure also provides an integrated circuit device. In one embodiment, the integrated circuit device includes a first substrate having a plurality of openings extending therethrough, and a second substrate coupled to the first substrate and including a plurality of epitaxially grown extensions each extending through a corresponding one of the plurality of openings. A plurality of first semiconductor devices are each coupled to the first substrate. A plurality of second semiconductor devices are each coupled to a corresponding one of the plurality of extensions.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A microelectronic device, comprising:
a first semiconductor substrate bonded to a second semiconductor substrate, the first semiconductor substrate including an opening through which an epitaxially grown portion of the second semiconductor substrate extends;
a first semiconductor device coupled to the first semiconductor substrate; and
a second semiconductor device coupled to the epitaxially grown portion of the second semiconductor substrate.

2. The device of claim 1 wherein the first semiconductor device comprises a p-type transistor and the second semiconductor device comprises an n-type transistor.

3. The device of claim 1 wherein the first semiconductor device comprises an n-type transistor and the second semiconductor device comprises a p-type transistor.

4. The device of claim 1 wherein the first and second semiconductor substrates have different crystallographic orientations.

5. The device of claim 1 wherein the first semiconductor substrate has a (1,1,0) crystallographic orientation and the second semiconductor substrate has a (1,0,0) crystallographic orientation.

6. The device of claim 1 wherein the first semiconductor substrate has a (1,0,0) crystallographic orientation and the second semiconductor substrate has a (1,1,0) crystallographic orientation.

7. The device of claim 1 further comprising a dielectric film interposing a sidewall of the opening and the epitaxially grown portion of the second semiconductor substrate.

8. The device of claim 1 further comprising a shallow trench isolation interposing a sidewall of the opening and the epitaxially grown portion of the second semiconductor substrate, the shallow trench isolation spanning the thickness of the first semiconductor substrate and extending into the second semiconductor substrate.

9. The device of claim 1 further comprising an oxide layer interposing the first semiconductor substrate and a bulk portion of the second semiconductor substrate, the opening also extending through the oxide layer.

10. The device of claim 1 further comprising a silicon dioxide layer interposing the first semiconductor substrate and a bulk portion of the second semiconductor substrate, the opening also extending through the silicon dioxide layer.

11. The device of claim 1 further comprising an implanted oxide layer interposing the first semiconductor substrate and a bulk portion of the second semiconductor substrate, the opening also extending through the implanted oxide layer.

12. The device of claim 1 wherein the first semiconductor substrate is a silicon-on-insulator substrate.

13. A method of manufacturing a microelectronic device, comprising:
coupling a first semiconductor substrate to a second semiconductor substrate;
patterning an opening in the first semiconductor substrate;
growing epitaxially an extension of the second semiconductor substrate through the opening;
forming a first semiconductor device on the first semiconductor substrate; and
forming a second semiconductor device on the extension of the second semiconductor substrate.

14. The method of claim 13 wherein the first semiconductor device comprises a p-type transistor and the second semiconductor device comprises an n-type transistor.

15. The method of claim 13 wherein the first semiconductor device comprises an n-type transistor and the second semiconductor device comprises a p-type transistor.

16. The method of claim 13 wherein the first and second semiconductor substrates have different crystallographic orientations.

17. The method of claim 13 wherein the first semiconductor substrate has a (1,1,0) crystallographic orientation and the second semiconductor substrate has a (1,0,0) crystallographic orientation.

18. The method of claim 13 wherein the first semiconductor substrate has a (1,0,0) crystallographic orientation and the second semiconductor substrate has a (1,1,0) crystallographic orientation.

19. The method of claim 13 further comprising forming a dielectric film on the first semiconductor substrate opposite the second semiconductor substrate and one at least a portion of a surface of the opening before epitaxially growing the extension of the second semiconductor substrate.

20. The method of claim 19 further comprising planarizing the first semiconductor substrate, the dielectric film, and the extension of the second semiconductor substrate to form a substantially planar surface collectively therefrom.

21. The method of claim 20 wherein planarizing includes substantially removing all of the dielectric film not located in the opening.

22. The method of claim 13 further comprising forming a shallow trench isolation separating the first semiconductor substrate and the extension of the second semiconductor substrate, the shallow trench isolation spanning the thickness of the first semiconductor substrate and extending into the second semiconductor substrate.

23. The method of claim 13 further comprising forming an oxide layer proximate an interface between the first semiconductor substrate and the second semiconductor substrate prior to forming the opening, the opening also extending through the oxide layer.

24. The method of claim 23 wherein forming the oxide layer includes implanting an oxide through at least a portion of the first semiconductor substrate, the opening also extending through the implanted oxide layer.

25. The method of claim 13 wherein coupling the first semiconductor substrate to the second semiconductor substrate includes bonding the first semiconductor substrate to the second semiconductor substrate.

26. The method of claim 25 wherein the first and second semiconductor substrates comprise first and second wafers, respectively, and wherein bonding comprises wafer bonding.

27. An integrated circuit device, comprising:
a first semiconductor substrate having a plurality of openings extending therethrough;
a second semiconductor substrate coupled to the first semiconductor substrate and including a plurality of epitaxially grown extensions each extending through a corresponding one of the plurality of openings;
a plurality of first semiconductor devices each coupled to the first semiconductor substrate; and
a plurality of second semiconductor devices each coupled to a corresponding one of the plurality of extensions.

28. The integrated circuit device of claim 27 wherein ones of the plurality of first semiconductor devices each comprise a p-type transistor and ones of the plurality of second semiconductor devices each comprise an n-type transistor.

29. The integrated circuit device of claim 27 wherein ones of the plurality of first semiconductor devices each comprise an n-type transistor and ones of the plurality of second semiconductor devices each comprise a p-type transistor.

30. The integrated circuit device of claim 27 wherein the first and second semiconductor substrates have different crystallographic orientations.

31. The integrated circuit device of claim 27 wherein the first semiconductor substrate has a (1,1,0) crystallographic orientation and the second semiconductor substrate has a (1,0,0) crystallographic orientation.

32. The integrated circuit device of claim 27 wherein the first semiconductor substrate has a (1,0,0) crystallographic orientation and the second semiconductor substrate has a (1,1,0) crystallographic orientation.

33. The integrated circuit device of claim 27 further comprising a plurality of dielectric films each interposing a sidewall of one of the plurality of openings and a corresponding one of the plurality of extensions of the second semiconductor substrate.

34. The integrated circuit device of claim 27 further comprising a plurality of shallow trench isolation structures each interposing a sidewall of one of the plurality of openings and a corresponding one of the plurality of extensions of the second semiconductor substrate, spanning the thickness of the first semiconductor substrate, and extending at least partially into the second semiconductor substrate.

35. The integrated circuit device of claim 27 further comprising an oxide layer interposing the first semiconductor substrate and a bulk portion of the second semiconductor substrate, the plurality of openings each also extending through the oxide layer.

36. The integrated circuit device of claim 35 wherein the oxide layer comprises silicon dioxide.

37. The integrated circuit device of claim 35 wherein the oxide layer comprises an implanted oxide layer.

38. The integrated circuit device of claim 27 wherein at least one of the first and second semiconductor substrates is a silicon-on-insulator substrate.
